(19) United States
(12) Patent Application Publication
(10) Pub. No.: US 2006/0108604 A1
(43) Pub. Date: May 25, 2006

(54) Bipolar transistor and a method of fabricating said transistor

(75) Inventors: Sylvain Blayac, Mimet (FR); Andre Scavennec, Paris (FR)

Correspondence Address: SUGHRUE MION, PLLC, 2100 PENNSYLVANIA AVENUE, N.W., SUITE 800, WASHINGTON, DC, 20037, US

(73) Assignee: ALCATEL

(21) Appl. No.: 11/280,261

(22) Filed: Nov. 17, 2005

(30) Foreign Application Priority Data
Nov. 18, 2004 (FR) 0452670

(51) Int. Cl. H01L 29/739

(52) U.S. Cl. 257/197

(57) ABSTRACT

The invention proposes a bipolar transistor comprising a substrate, emitter, base, and collector layers and, if appropriate, contact layers. The base layer is formed from a GaAsSb material. The transistor also has at least one transition layer formed from a GaInP material between the emitter layer and the base layer. The presence and composition of the transition layer allows the profile of the conduction band of the transistor to be shaped to optimize performance. Further, the composition of the transition layer facilitates fabrication of the transistor by selective etching. The invention also relates to a circuit comprising a bipolar transistor of the invention. The invention also proposes a method of fabricating a transistor in accordance with the invention.

The invention relates to a bipolar transistor and to a method of fabricating said transistor.

The term “semiconductor” is used below to designate a material having electrical conductivity lying between that of conductors and that of insulators and varying as a function of the concentration of impurities or dopants. A semiconductor is doped by introducing atoms of a selected impurity into its mass in order to influence its local or overall conductivity.

The term “energy band” means a set of close-lying discrete energy levels in a material, more particularly a crystalline solid. Said levels may be occupied by electrons, and substitute for the levels in an isolated atom in the condensed material. As an example, the “conduction band” is an empty or partially occupied band in which the electrons may carry a current (termed the conduction current). The “valence band” is a band with lower energy than the preceding band, occupied by electrons which do not participate in electrical conductivity. The term “bandgap” means the interval corresponding to the minimum energy required for an electron to pass from a level located in the valence band to a level in the conduction band.

When an electron is excited from the valence band to the conduction band, it is as if a “hole” has been created in the valence band. Said hole may be modeled as a particle of charge opposite to that of the electron and capable of carrying an electric current.

The term “recombination” means de-excitation of an electron, for example from the conduction band to the valence band, or annihilation of an electron/hole pair. Said de-excitation may be stimulated or spontaneous.

Transistors are components based on semiconductors used to control the passage of an electric current; they constitute basic elements of electronic circuits. A transistor mainly comprises three semiconductor layers (the layers are termed the “emitter”, the “base”, and the “collector”) joined by two junctions. The layers may be “positively” doped (P) or “negatively” doped (N). Two types of transistor can be distinguished: the NPN transistor (N emitter, P base, N collector) and the PNP transistor (P emitter, N base, P collector).

In more detail, in a conventional homojunction NPN bipolar transistor, electrons pass from the emitter to the collector. That transistor comprises two PN junctions: emitter-base and base-collector, mounted head-to-tail. When functioning normally, the emitter-base junction is biased in the forward direction, which allows preferential injection of majority carriers from the emitter (electrons) into the base, provided that doping of the base is less than that of the emitter. Said carriers diffuse towards the base-collector junction which is biased in the reverse direction. The electric field created in that field zone, termed the space charge zone or depleted zone, then encourages electrons to collect in the collector. Very high frequency operation, however, requires both a thin base to obtain a short transit time for electrons crossing it, and strong doping of the base, to obtain a low base resistance, which is necessary in order to reduce charging time of the “resistance×capacitance” type. Strong base doping, with even stronger doping of the emitter to conserve the gain, leads to a very high emitter-base capacitance, which therefore limits high frequency operation. Thus, it becomes necessary to modify the structure of the layers to overcome this constraint, for example by using a base-emitter heterojunction.

A bipolar transistor is termed a single heterojunction bipolar transistor (SHBT) when the two contiguous semiconductor layers (forming the emitter-base junction) have different atomic compositions and as a result do not have the same bandgap, but they may if appropriate have the same lattice parameters. An emitter is thus used which has a bandgap Eg which is wider than that of the base. As an example, InP materials (Eg=1.35 eV [electron volts]) and InGaAs materials (Eg=0.75 eV) can be used respectively for the emitter and for the base. With moderate emitter doping, such a combination can allow the base to be strongly doped to reduce its resistance while keeping it thin. The advantage of a heterojunction bipolar transistor structure over that of homojunction transistors thus lies in the possibility of increasing high frequency performance while retaining high gain. Such an InP/InGaAs emitter-base heterojunction transistor is highly suitable for low voltage operation. When high voltages have to be used, it becomes necessary to improve the breakdown voltage.

To this end, it is possible to use double heterojunction bipolar transistors (DHBTs), i.e. having a second base-collector heterojunction in addition to the emitter-base heterojunction. The second heterojunction improves the breakdown voltage by means of a collector material having a large bandgap (for example InP). However, said second heterojunction creates a discontinuity in the conduction band, known as a “spike”. In the case of an emitter-base junction biased in the forward direction, said discontinuity is advantageous since electrons are injected into the base with excess energy. In contrast, it blocks electrons at the base-collector junction and thus degrades the gain of the transistor.

One solution to this problem consists of inserting transition layers between the base and the collector to smooth the variations in the conduction band; this produces a transistor with very precise characteristics. However, although widely used, that solution is not entirely satisfactory when high collector-current densities are used. The resulting charge of the electrons in transit causes a large amount of deformation in the bands at the base-collector heterojunction and electrons are blocked at the base.

Further, the multi-layered structure of the collector involves more complex fabrication methods because of the behavior of GaInAsP layers and their interfaces during chemical etching, and because of high leakage currents due to the presence of multiple interfaces in a region with a high electric field, which in turn limits the breakdown voltage.

A further scheme for aligning the conduction band has been proposed in U.S. Pat. No. 5,349,201 in order to overcome the problem of collection at the base-collector interface. That document proposes a heterojunction bipolar transistor comprising a InGaAs, InP or AlInAs collector layer formed over an InP substrate. The base layer of GaAsSb (more particularly GaAs_{0.53}Sb_{0.47}) is formed over the collector layer and the emitter layer, formed from AlInAs or InP, is formed over the base layer. The base layer may be formed from GaAsSb doped with beryllium or carbon.

The conduction band alignment thus obtained allows effective electron collection since the conduction band of the collector formed from InP, for example, is naturally below the level of that of the base, formed from GaAsSb (by about 0.17 eV for lattice-matched materials), thus forming what is known as a type II heterojunction. The effectiveness of that concept has been clearly demonstrated (see, for example, the article by M. W. Dvorak, C. R. Bolognesi, O. J. Pitts, S. P. Watkins, “300 GHz InP/GaAsSb/InP Double HBTs with High Current Capability and BVCEO>6 V”, IEEE Electron Dev Lett 22 (8), 361-363 (2001)). The proposed configuration results in transistor characteristics which are entirely acceptable without having recourse to transition layers, and thus with no additional interfaces. The associated methods are simplified thereby, and the collector-base junction offers improved qualities both in static mode and in dynamic mode.

However, for a transistor with an InP emitter, the relative positioning of the conduction bands, which is favorable for a collector junction (base-collector junction), is not favorable for an emitter-base heterojunction where the discontinuity creates a notch in the conduction band in the forward biased condition. Said notch has undesirable effects on (i) current gain at low current density, due to recombinations caused at the emitter-base heterojunction; (ii) capacitance of the emitter-base junction, which increases because of the accumulation of electrons at the junction; and (iii) conditions for injecting electrons into the base.

In order to overcome the problem created at the emitter-base junction, a mismatched base material (with respect to the InP lattice parameter) which is rich in arsenic (allowing the value of the discontinuity to be reduced) was used by the above team with some success. Further, it has been proposed (see, for example, P. Bove, H. Lahreche, R. Langer, “InP/GaAsSb and (Al,Ga)InAs/GaAsSb DHBT material grown in a 4 inch multiwafer MBE machine”, Proc Indium Phosphide & Related Materials Conference: IEEE Catalog 02CH37307; pp 607-610; 2002) to replace the InP material of the emitter with a quaternary GaInAlAs material, enabling said notch to be removed by eliminating the discontinuity and current gain to be restored at low currents.

Other materials for the emitter have been tested for the same purposes, for example the InAlAs material having a lattice that matches the lattice of InP. That type of material used as the emitter can produce a discontinuity in the conduction bands which is reversed with respect to an InP/GaAsSb heterojunction, enabling electron injection to be quasi-ballistic, which primarily results in a minimum transit time across the base. However, those solutions (AlInAs or AlGaInAs materials for the emitter layer) suffer from certain technological disadvantages. The above two types of material limit the possibility of using selective etching methods. In particular, they cannot naturally stop chemical etching in the base layer during emitter formation. That aspect is particularly important when high fabrication yields are required, such as in the fabrication of integrated circuits, for example.

Thus, there is a need for a high performance bipolar transistor that is suitable for being fabricated by selective etching, and a need for a method of fabricating said transistor.

The invention thus proposes a bipolar transistor comprising: a substrate, a collector layer, a base layer formed from a GaAsSb material, an emitter layer, and at least one transition layer formed from a GaInP material between the emitter layer and the base layer.

In its various embodiments, the bipolar transistor of the invention includes one or more of the following features:
the substrate is formed from an InP material, the emitter layer is formed from an InP material and the collector layer is formed from an InP material;
the transition layer is formed from a material with the composition Ga₁₋ₓInₓP, the index x being in the range 0.60 to 1.00;
the index x is substantially in the range 0.82 to 1.00;
the transition layer is formed from a material with composition Ga₁₋ₓInₓP with a variable index x, substantially equal to 1.00 at the interface between the transition layer and the emitter layer and more than 0.60 at the interface between the transition layer and the base layer;
the index x is substantially equal to 0.82 at the interface between the transition layer and the base layer;
the transistor of the invention comprises a plurality of transition layers, each of the transition layers comprising a Ga₁₋ₓInₓP composition with an index x in the range 1.00 to a value of more than 0.60, the values of the index x decreasing substantially from the emitter to the base;
the index x of each of the layers is more than 0.82;
the index x of the transition layer varies substantially continuously from a value or more than 0.60 to 1.00 between the base layer and the emitter layer;
the index x varies substantially continuously from 0.82 to 1.00 between the base layer and the emitter layer; and
the lattice parameter of the base formed from GaAsSb does not match the lattice parameter of the emitter layer.

The invention also provides a circuit comprising a bipolar transistor of the invention.

The invention also proposes a method of fabricating a transistor in accordance with the invention, comprising a step a) of forming said at least one transistor layer from a GaInP material.

In its various embodiments, the method of the invention includes one of the following features:
step a) of forming the transition layer is a step of growing the transition layer by selective epitaxy; and
step a) of forming the transition layer is a step of selective etching of the transition layer.

Other characteristics and advantages of the invention become apparent from the following description of embodiments of the invention, given by way of example and made with reference to the accompanying drawings, in which:

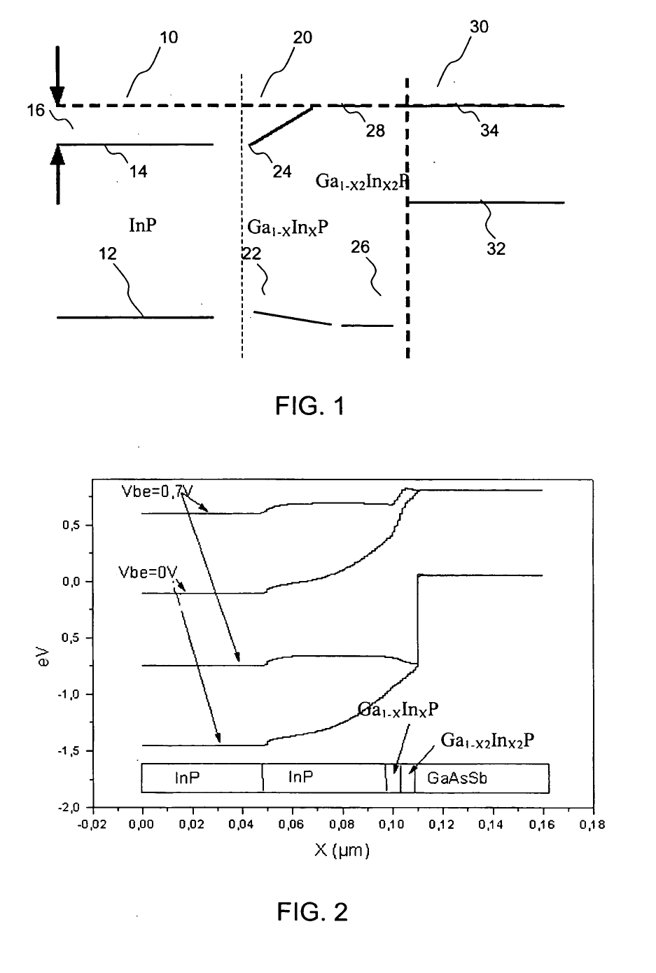

FIG. 1 is a diagram of the band alignment in a bipolar transistor in an embodiment of the invention;

FIG. 2 is an example of a band diagram obtained for the embodiment of FIG. 1;

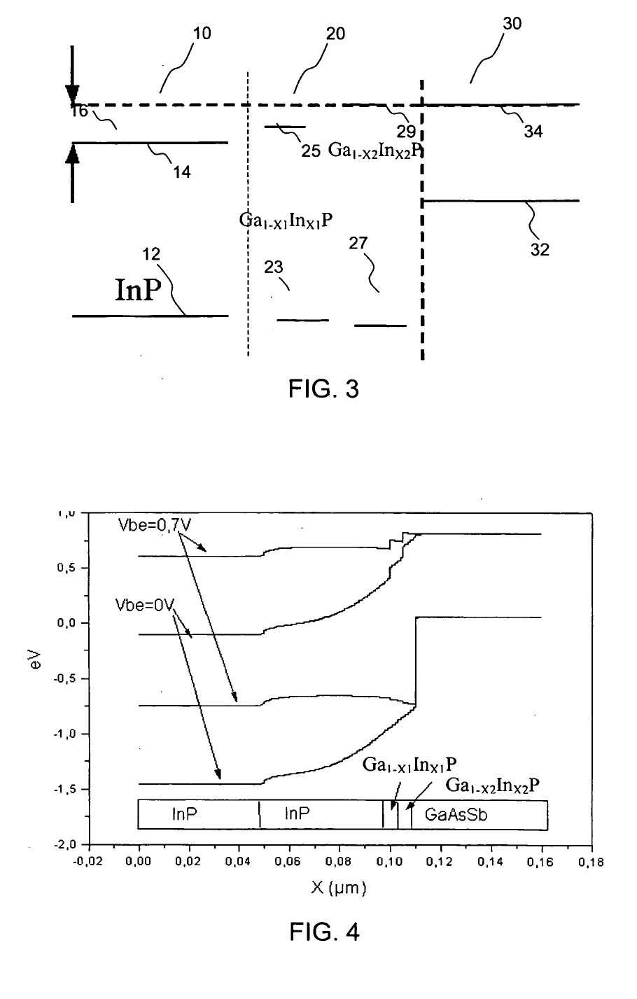

FIG. 3 is a diagram of the band alignment in a bipolar transistor in another embodiment of the invention; and

FIG. 4 is an example of a band diagram obtained for the embodiment of FIG. 3;

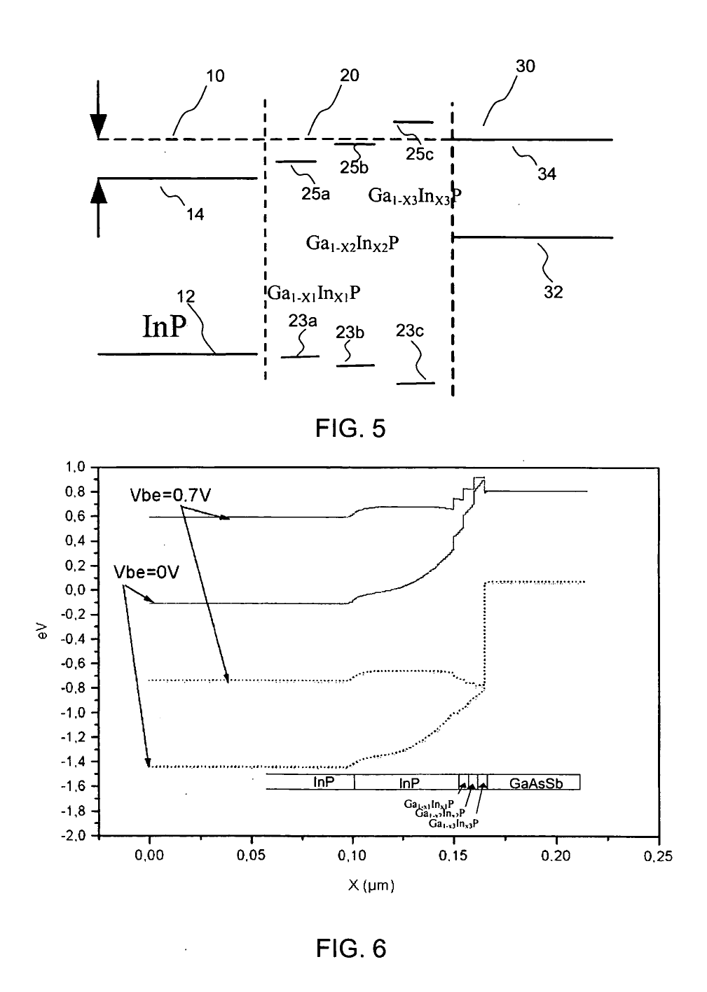

FIG. 5 is a diagram of the band alignment in a bipolar transistor in a third embodiment of the invention;

FIG. 6 is an example of a band diagram obtained for the embodiment of FIG. 5.

The invention proposes a bipolar transistor comprising a substrate, emitter, base and collector layers and, if appropriate, contact layers. The base layer is formed from a GaAsSb material. The transistor also has at least one transition layer formed from a GaInP material, between the emitter layer and the base layer. The presence and the composition of the transition layer allow the profile of the conduction band of the transistor to be shaped to optimize performance. Further, the composition of the transition layer facilitates fabrication of the transistor by selective etching.

FIG. 1 is a diagram of the band alignment in the materials of the emitter, the transition layer, and the base of a bipolar transistor in an embodiment of the invention. The ordinate shows the energy levels, not to scale, and the abscissa shows a privileged direction of the transistor. This direction, denoted X, is substantially perpendicular to the successive layers of the emitter, the transition, and the base of the bipolar transistor of the invention. The corresponding zones in FIG. 1 are designated by the reference numerals 10, 20, and 30. Said zones are separated by vertical dotted lines in FIG. 1. A first series of segments 14, 24, 28, 34 denotes the conduction band alignment along the X direction. A second series of segments 12, 22, 26, and 32 denotes the alignment of the valence band. More precisely, segments 14, 24, and 28 together and the segment 34 respectively represent the characteristic energy values of the conduction band of the emitter, the transition and the base layers of the transistor. Similarly, segments 12, 22, and 26 together and the segment 32 respectively represent the characteristic values of the energies of the valence band of the emitter, the transition, and the base layers of the transistor. The distance between the two arrows in FIG. 1 represents a characteristic energy gap between the conduction band of the emitter layer and the conduction band of the base layer of the bipolar transistor. That distance is typically 0.17 eV when an InP emitter layer and a matching GaAsSb base layer are used.

Referring to FIG. 1, the bipolar transistor of the invention has at least one transition layer formed from a GaInP material between the emitter layer and the base layer, which base layer is formed from a GaAsSb material which has been doped. The composition of the transition layer, i.e. a ternary GaInP alloy, allows fabrication of the transistor by selective etching due to the presence of phosphorus. Etching stops naturally on the GaAsSb base, which keeps the thickness of the base layer homogeneous and thus produces excellent yields.

Preferably, the base layer is formed from a doped GaAsSb material having substantially the composition GaAs_{0.51}Sb_{0.49}, which produces a lattice match with the InP material.

Preferably again, the transistor substrate and the emitter layer are formed from an InP material, respectively semi-insulating and doped. Preferably again, the collector layer is formed from a doped InP material. The bipolar transistor of the invention is then a double heterojunction bipolar transistor, thereby offering the advantages discussed above.

However, it is possible to provide a GaAs substrate with the collector layer being formed from an InP material. In such a case, metamorphic growth is carried out on the GaAs substrate. A buffer layer is inserted between the substrate and the collector layer to absorb the difference in the respective lattice parameters. Metamorphic epitaxy can produce good quality crystallographic structures even with a lattice parameter which is substantially different from that of the substrate on which they are deposited.

In an embodiment, the transition layer is formed from a material with composition Ga₁₋ₓInₓP in which the index x may be adjusted. Adjusting the composition of the layer can then allow the conduction band to be shaped, in particular at the emitter-base junction.

Preferably, said index x is in the range 0.60 to 1.00. The index x may, for example, be fixed at a value of 0.82 at the interface between the transition layer and the base layer. When said index is reduced to about 0.82 at said interface, the discontinuity in the conduction band practically disappears, i.e. the energy jump ΔE_{c(GaInP/GaAsSb)} becomes substantially zero at the interface for a composition based on GaAs_{0.51}Sb_{0.49}. The value of close to 0.82 was calculated by interpolation of known information pertaining to the positions of the Fermi level and the bandgap energy in InP and GaP materials (see, for example, H. Hasegawa and H. Ohno, J Vac Sci Technol B4 (1986), pp 1130). The undesirable effects linked to the discontinuity in the conduction band at the emitter-base junction on the current gain and emitter-base capacitance are thereby reduced or even eliminated. The reduction or removal of the discontinuity can produce improved current gain due to the reduction in recombination at the junction and lower capacitance (accumulation of unwanted charge at the discontinuity being itself reduced).

In an embodiment, it is possible to further improve the conditions for injection into the base by selecting an index which is less than 0.82 (for example substantially equal to 0.70), thereby causing the appearance of a discontinuity allowing quasi-ballistic injection of carriers (electrons) into the base.

In an embodiment of the invention, the index x of the transition layer changes from 0.82 to 1.00 between the base layer and the emitter layer. The value of the index at the interface between the transition layer and the base layer, namely 0.82, can eliminate the discontinuity, as discussed above. The value of the index at the emitter-transition layer interface is 1.00, although the composition of the transition layer is substantially the same as that of the emitter layer at that region. The interface is thus gradual, there is thus no longer a discontinuity at that region, thereby avoiding undesirable electronic phenomena, as discussed above.

The index x may, for example, vary substantially continuously between 1.00 and 0.82 in the emitter-base direction, in which case all of the discontinuities are removed, as shown in segments 20 and 22 in FIG. 1.

If appropriate, two transition layers may be provided, one with composition Ga₁₋ₓInₓP in which the index x is progressive (varying continuously from 1.00 to 0.82 in the emitter-base direction) and the other with composition Ga₁₋ₓ₂Inₓ₂P in which x2=0.82. Such a transition layer configuration can produce a suitable profile for the conduction band without any notable discontinuities or sharp variations.

FIG. 2 shows an example of a band diagram obtained using the embodiment of FIG. 1. The ordinate shows the energy levels (electron volts, eV) and the abscissa shows a privileged direction of the transistor, as in FIG. 1, but here the conduction and valence bands of the highly doped portion formed from InP of the emitter are also shown, in the left hand part of the figure. FIG. 2 shows the results of a physical simulation for different bias conditions. In a first case, there exists a base-emitter voltage (Vbe) fixed by the bias current at close to 0.7 volts, and representative of the normal bias conditions, while in the second case, said voltage is zero. The two upper curves on the energy axis show the change in the conduction band; the two lower curves show the valence band. The relative thicknesses of the emitter-transition-base layers are shown in the scale shown at the bottom of the figure.

In the embodiment of FIG. 2, said scale concerns successive layers of InP (doped at 1×10¹⁹ cm⁻³) InP (doped at 3×10¹⁷ cm⁻³), Ga₁₋ₓInₓP (doped at 1×10¹⁶ cm⁻³, index x progressive and continuous), GaInP (doped at 1×10¹⁶ cm⁻³, index x2=0.82), and GaAsSb (doped at 3×10¹⁹ cm⁻³).

The physical simulation was carried out using software developed by Opto+ Alcatel Recherche & Innovation (see, for example, F. Palmier, “Notice de BCBV”, CNET France Telecom Internal Report, 1998). That software can simulate structures as a function of the epitaxial layers from which they are composed, from their doping, and from their bias, to model physical properties such as band diagrams, carrier and current densities, the electric field profile, etc. The production of diagrams of the type shown in FIG. 2 is useful to the skilled person in assessing the characteristics of the transistor. Such a diagram may incorporate the results of experimental measurements, for example of the photoluminescence or electroluminescence type, but a model has to be used as there is no possibility of measuring the function shown in FIG. 2 directly, hence the simulation.

As shown in FIG. 2, inserting transition layers one of which has the composition Ga₁₋ₓInₓP in which the index x is progressive (varying continuously from 1.00 to 0.82), and the other of which has the composition Ga₁₋ₓ₂Inₓ₂P (x2=0,82), allows the variation in the bands to be re-designed, in particular in the conduction band, so as to minimize discontinuities, both for Vbe=0.7 V and for Vbe=0.0 V.

FIG. 3 diagrammatically shows the band alignment in a bipolar transistor of a further embodiment of the invention. FIG. 3 has the same reference numerals as FIG. 1, with the exception of segments 25 and 29 which now symbolize the conduction band in the X direction at the transition layer (similarly with segments 23 and 27 for the valence band).

In the embodiment of FIG. 3, the index x varies stepwise, i.e. discontinuously: in this case there are one or more transition layers, each of said layers having a distinct index x. The persistent discontinuities obtained in this embodiment are, however, smaller than those obtained in the case of an InP/GaAsSb type junction, i.e. an emitter-base junction without a transition layer.

As an example, it is possible to provide just a single transition layer with a composition Ga₁₋ₓ₁Inₓ₁P in which the index x1 has an intermediate value between the values 0.82 and 1, respectively allowing a reduced discontinuity at the interface between the transition layer and the base layer and at the interface between the emitter layer and the transition layer with respect to the discontinuity appearing in the absence of the transition layer. This value of the index x1 may, for example, be fixed at 0.9. The presence of only a single transition layer with index x between the values of 0.82 and 1 can reduce the band discontinuity at the interface entering the base.

As for the embodiment of FIG. 3, it is possible to provide two transition layers, one with an index x1 with a substantially constant intermediate value of 0.91 and the other with a substantially constant index x2 equal to 0.82, meaning that the discontinuity at the interface between the transition layer and the base layer can be removed while the value 0.91 is an intermediate value which allows the discontinuities to be distributed around said layer, as shown diagrammatically in FIG. 3.

Having recourse to one or more transition layers Ga₁₋ₓInₓP with a gradual index x, i.e. varying in steps, reduces the discontinuities at the emitter-base junction. This results in improved gain and improved stray capacitance. The use of the optimized bipolar transistor devices of the invention can also allow cutoff frequencies of well above 300 GHz [gigahertz] and current gains of the order of 100 to be envisaged. At the same time, the fabrication of such bipolar transistors is greatly improved, given that the possibility of selective emitter-base etching is preserved primarily because of the composition of the transition layer or layers.

Preferably, the thickness of a transition layer is less than 40 nm [nanometers] and more preferably less than 30 nm. A typical transition layer thickness is of the order of 20 nm, regardless of whether the transition layer has an index x that is constant or progressive. Such layer thicknesses can cut down the deleterious effects of lattice mismatches between the emitter and base layers and the transition layer.

It should be noted that the lattice parameter of a single Ga₁₋ₓInₓP transition layer with index x=0.82 (i.e. a=5.79 Å [Angstroms], ZnS type structure) is not identical to that of InP (a=5.87 Å, same crystallographic structure). The lattice mismatch thus manifests itself in a relative offset of 1.4%. Such a value remains relatively small, however, having regard to the lattice mismatches normally experienced in the art (for mismatched layer thicknesses of the order of 20 nm).

FIG. 4 shows an example of a band diagram obtained using the embodiment of FIG. 3. FIG. 4 is similar in presentation to FIG. 2. The physical simulation was also carried out using digital simulation software.

In the embodiment of FIG. 4, the scale at the bottom of the figure shows successive layers of InP (doped at 1×10¹⁹ cm⁻³), InP (doped at 3×10¹⁷ cm³), Ga₁₋ₓ₁Inₓ₁P (doped at 1×10¹⁶ cm⁻³, index x1=0.91), Ga₁₋ₓ₂Inₓ₂P (doped at 1×10¹⁶ cm⁻³, index x2=0.82), and GaAsSb (doped at 3×10¹⁹ cm⁻³).

As shown in FIG. 4, inserting transition layers with a gradual index x also allows the bands to be shaped, in particular the conduction band, to minimize the discontinuities (in the case in which Vbe=0.7 V or Vbe=0.0 V). The presence of two transition layers induces two small discontinuities upstream of the base, on the emitter side. Each of said discontinuities is, however, smaller than that obtained for a single InP/GaAsSb junction (typically 0.17 eV). Inserting transition layers with a constant index x can thus divide the amplitude of the discontinuities and thereby restrict the undesirable effects discussed above.

FIG. 5 diagrammatically shows the band alignment of a bipolar transistor of a third embodiment of the invention. In this embodiment, the transport conditions across the base are to be improved by a discontinuity such that the heterojunction between the last transition layer and the Ga₁₋ₓ₃Inₓ₃P/GaAsSb base is of type I. FIG. 5 shows the same reference numerals as FIG. 1, with the exception that the segments 25a, 25b and 25c now represent the conduction band in the X direction at the transition layer (similarly with the segments 23a, 23b, 23c for the valence band).

In the embodiment of FIG. 5, the index x varies discontinuously, as was the case for FIG. 3. Said index x takes the values x1, x2 and x3 in succession, so that the conduction band of the transition layer closest to the base is located above the conduction band of the base.

FIG. 6 shows an example of a band diagram obtained using the embodiment of FIG. 5. FIG. 6 is similar in presentation to FIGS. 2 and 4. The physical simulation was also made using digital simulation software.

Referring to FIG. 6, the scale at the bottom of the figure shows successive layers of InP (doped at 1×10¹⁹ cm⁻³), InP (doped at 3×10¹⁷ cm⁻³), Ga₁₋ₓ₁Inₓ₁P (doped at 1×10¹⁶ cm⁻³, index x1=0.9), Ga₁₋ₓ₂Inₓ₂P (doped at 1×10¹⁶ cm⁻³, index x2=0.8), Ga₁₋ₓ₃Inₓ₃P (doped at 1×10¹⁶ cm⁻³, index x3=0.7), and GaAsSb (doped at 3×10¹⁹ cm⁻³).

Again, as shown in FIG. 6, inserting transition layers with a gradual index x allows the bands, in particular the conduction band, to be shaped in order to minimize the discontinuities. The presence of three transition layers induces three small discontinuities upstream of the base, on the emitter side. The existence of a discontinuity with the base, such that the conduction band of the emitter including the transition zone is located above the conduction band of the base, allows energetic electrons to be injected into it which may cross it more rapidly than in the preceding cases, further improving the characteristics of the transistor.

As discussed above, the base material preferably has a composition which is close to that corresponding to a lattice match with InP. However, in an embodiment, the GaAsSb base material is mismatched (with respect to the lattice parameter for the InP emitter layer), i.e. the amount of arsenic in the composition is slightly increased (moving from 0.53 to 0.56 or 0.60). This provides an additional parameter for adjusting (in particular reducing) the discontinuity at the emitter-base junction.

The bipolar transistor of the invention may also conventionally comprise metallic parts for the emitter contact, the base contact, and the collector contact, and semiconductor contact parts such as the sub-collector, etc. The metallic contact parts are formed from Ti/Pt/Au, for example.

The invention also relates to a circuit, in particular an integrated circuit, comprising a plurality of transistors in accordance with the invention. The properties obtained for said transistor and its fabrication potential render it propitious for use in a circuit.

The invention also provides a method of fabricating a transistor in accordance with the invention.

Methods of fabricating transistors and circuits based on InP are known and highly developed (see, for example, S. Blayac “Transistor bipolaire á double hétérojonction InP/InGaAs pour circuits de communications optiques à très haut debit” [“Double heterojunction InP/InGaAs bipolar transistor for very high speed optical communications circuits”], Doctoral Thesis, Montpellier II University, 2000).

Firstly, the method of the invention may comprise preliminary steps of epitaxial growth, in particular of the collector layer, the base layer, and the emitter later, as is known in the art.

In this respect, conventional epitaxy techniques may be used, such as MBE (molecular beam epitaxy), or molecular jet epitaxy, or MOVPE (metal organic vapor phase epitaxy). These techniques are widely known. It is also possible to use a CBE (chemical beam epitaxy) method which combines aspects of the two preceding techniques. In particular, it combines the concept of a molecular growth regime with that of using gaseous sources (see, for example, J. L. Benchimol, F. Alexandre, B. Lamare, P. Legay, “Benefits of chemical beam epitaxy for micro and optoelectronic applications”, Prog Crystal Growth and Charact, vol 3, pp 473-495, 1996).

The elements in the layers to be deposited (for example indium (In), gallium (G), arsenic (As), and phosphorus (P)) may be obtained by decomposing sources at very high temperatures by pyrolysis or cracking. After cracking, the gaseous species are deposited on the substrate. A vacuum is maintained to evacuate the unrequired products after decomposition, in particular radicals. Further, a low pressure (˜10⁻⁶ torr) offers conditions in which the mean free path of the molecules is more than the source-substrate distance, which allows the species to reach the substrate surface without suffering substantial interactions.

The method of the invention may typically comprise the steps of lithography, deposition, etching, passivation and planarization. In particular, said method may comprise the steps of lithography of the emitter contact, deposition of the emitter contact (for example Ti/Pt/Au) and, after etching the GaInAs contact layers of the emitter, chemical etching of the InP mesa emitter. A solution suitable for selective etching of the InP part of the mesa emitter is of the HCl+H₃PO₄ type.

A key step in the method of the invention is the formation of said at least one transition layer formed from a GaInP material.

In an implementation of the invention, this step comprises a step of selective etching of the transition layer. Regarding etching of the transition layer, a suitable solution is of the same type as that used for the InP layer, for example based on H₃PO₄ and HCl. Because of the compositions involved (namely GaInP for the transition layer and GaAsSb for the base), chemical etching stops naturally at the base. Such a feature means that high fabrication yields can be attained.

The method of the invention may also comprise steps of lithography of the base contact, deposition of the base contact (for example Pt/Ti/Pt/Au), and chemical etching of the mesa base.

The method may also comprise one or more of the following steps: lithography of the collector contact, deposition of the collector contact (Ti/Pt/Au), protective lithography (insulation), chemical etching of the mesa collector, passivation with polyimide, vias lithography, vias etching and deposition of an interconnection metal (see, for example, S Withitsoonthorn, “Photodiode UTC et oscillateur differential commandé en voltage à base de TBdH InP pour récupération d'horloge dans un réseau de transmission optique à très haut débit” [“Voltage controlled UTC photodiode and differential oscillator based on TBdH InP for clock recovery in a very high speed optical transmission network”], Doctoral Thesis, University of Paris 6.

In an implementation, step a) of forming the transition layer is a step of growing the transition layer by selective epitaxy, which step may follow a step of forming the base layer, for example. Depending on the gas present in the reactor in which growth is carried out, and depending on the nature of the surface material, epitaxy may or may not occur. In other words, the conditions are adjusted to obtain selective growth.

In the invention, the transistor and the method of fabricating said transistor are thus not only suitable for selective etching, but they are also capable of using selective epitaxy.

The above embodiments and implementations should be considered as being presented by way of a non-limiting illustration of the invention, which is not itself limited to the details provided here, but may be modified within the scope of the accompanying claims.

1. A bipolar transistor comprising:
a substrate formed from an InP material;
a collector layer formed from an InP material;
a base layer formed from a GaAsSb material;
an emitter layer formed from an InP material; and
at least one transition layer formed from a GaInP material between the emitter layer and the base layer.

2. The transistor of claim 1, in which the transition layer is formed from a material with the composition Ga₁₋ₓInₓP, the index x being in the range 0.60 to 1.00.

3. The transistor of claim 2, in which the index x is substantially in the range 0.82 to 1.00.

4. The transistor of claim 1, in which the transition layer is formed from a material with composition Ga₁₋ₓInₓP with a variable index x substantially equal to 1.00 at the interface between the transition layer and the emitter layer and more than 0.60 at the interface between the transition layer and the base layer.

5. The transistor of claim 4, in which the index x is substantially equal to 0.82 at the interface between the transition layer and the base layer.

6. The transistor of claim 1, comprising a plurality of transition layers, each of the transition layers comprising a Ga₁₋ₓInₓP composition with an index x in the range 1.00 to a value of more than 0.60, the values of the index x decreasing substantially from the emitter to the base.

7. The transistor of claim 6, in which the index x of each of the layers is more than 0.82.

8. The transistor of claim 2, in which the index x of the transition layer varies substantially continuously from a value or more than 0.60 to 1.00 between the base layer and the emitter layer.

9. The transistor of claim 8, in which the index x varies substantially continuously from 0.82 to 1.00 between the base layer and the emitter layer.

10. The transistor according to claim 1, in which the lattice parameter of the base formed from GaAsSb does not match the lattice parameter of the emitter layer.

11. A circuit comprising a transistor according to claim 1.

12. A method of fabricating a transistor according to claim 1, comprising a step:
a) of forming said at least one transition layer from a GaInP material.

13. The method of claim 12, in which step a) of forming the transition layer is a step of growing the transition layer by selective epitaxy.

14. The method of claim 12, in which step a) of forming the transition layer is a step of selective etching of the transition layer.
